(19) United States
(12) Patent Application Publication
(10) Pub. No.: US 2026/0243981 A1
(43) Pub. Date: Aug. 20, 2026

(54) THERMAL MANAGEMENT OF OPTICAL COMPONENTS

(71) Applicant: Lumentum Technology UK Limited, NORTHAMPTONSHIRE (GB)

(72) Inventor: Colin SMITH, Paignton (GB)

(21) Appl. No.: 19/182,155

(22) Filed: Apr. 17, 2025

Related U.S. Application Data
(60) Provisional application No. 63/759,759, filed on Feb. 18, 2025.

(51) Int. Cl. G02B 6/42; H10W 40/28; H10W 40/73; H10W 76/153

(52) U.S. Cl. CPC G02B 6/4271; H10W 40/28; H10W 40/73; G02B 6/4256; H10W 76/153

(57) ABSTRACT

In some implementations, an optical assembly may include a heat-generating device and a thermal dissipation component. The heat-generating device may be configured to generate heat during operation. The thermal dissipation component may include a first surface directly attached to a second surface of the heat-generating device to receive the heat generated by the heat-generating device. For example, the thermal dissipation component may contain a phase change material configured to undergo phase transitions between a first phase state and a second phase state, where the phase transitions may cause the heat to spread throughout the thermal dissipation component in one or more normal directions relative to a first direction in which the heat is received from the heat-generating device.

### CROSS-REFERENCE TO RELATED APPLICATION

This patent application claims priority to U.S. Patent Application No. 63/759,759, filed on Feb. 18, 2025, and entitled “THERMAL MANAGEMENT OF OPTICAL COMPONENTS.” The disclosure of the prior application is considered part of and is incorporated by reference into this patent application.

### TECHNICAL FIELD

The present disclosure relates generally to optical components and to thermal management of optical components.

### BACKGROUND

An optical module may have at least one of an optical transmission function or an optical receive function. In general, in order to implement the optical transmission function and/or the optical receive function, the optical module includes one or a plurality of optical sub-assemblies (OSAs).

An OSA may be configured to convert an electrical signal into an optical signal, or vice versa. For example, an OSA may be used for optical communications in which electrical signals are used to transmit or receive information in a digital format or an analog format. An OSA configured as a transmitter may be configured to convert an electrical signal into an optical signal and transmit the optical signal over an optical fiber connected to the OSA. An OSA configured as a receiver may be configured to receive an optical signal (e.g., the optical signal transmitted by the transmitter OSA) and convert the optical signal back into an electrical signal for signal processing (e.g., demodulation or decoding). An OSA configured as a transceiver that includes both a transmitter and a receiver may be configured to transmit and receive optical signals.

Thermal management in OSAs is critical, due to their role in converting electrical signals to optical signals and vice versa, which involves significant energy transfer and heat generation. OSAs, whether configured as transmitters, receivers, or transceivers, may be configured to operate within a range of operating temperatures to ensure reliable performance and signal integrity. Excessive heat can lead to signal degradation, increased error rates, and potential failure of the optical components.

### SUMMARY

In some implementations, an optical assembly includes a heat-generating device configured to generate heat during operation; and a thermal dissipation component, comprising a first surface directly attached to a second surface of the heat-generating device to receive the heat generated by the heat-generating device, wherein the thermal dissipation component contains a phase change material configured to undergo phase transitions between a first phase state and a second phase state, and wherein the phase transitions cause the heat to spread throughout the thermal dissipation component in one or more normal directions relative to a first direction in which the heat is received from the heat-generating device.

In some implementations, a method at an optical assembly includes performing, at a heat-generating device of the optical assembly, one or more operations that generate heat at the heat-generating device; and spreading, by a thermal dissipation component of the optical assembly, the heat generated during the one or more operations, wherein the thermal dissipation component contains a phase change material that transitions from a first phase state to a second phase state based at least in part on spreading the heat, and wherein transitioning from the first phase state to the second phase state spreads heat throughout the thermal dissipation component in one or more normal directions relative to a first direction in which the heat is received from the heat-generating device.

In some implementations, an optical assembly includes a housing that defines an enclosure, wherein the housing comprises sidewalls and a base that extends between the sidewalls, and wherein one of the sidewalls comprises an optical port configured to at least one of receive a receive optical signal or transmit a transmit optical signal; at least one component integrated within the enclosure, wherein the at least one component is configured to generate heat during operation; and a thermal dissipation component inside of the enclosure, wherein: a first surface of the thermal dissipation component is directly attached to a second surface of the at least one component to receive heat from the at least one component, the thermal dissipation component contains a phase change material that is configured to undergo phase transitions between a first phase state and a second phase state, the thermal dissipation component is configured to utilize the phase transitions to spread heat throughout the thermal dissipation component in a two-dimensional plane that is perpendicular to a first direction in which the heat is received from the at least one component, and the thermal dissipation component is configured to equalize at least one of a heat load or a temperature gradient of the at least one component.

### BRIEF DESCRIPTION OF THE DRAWINGS

FIG. 1 shows a cross-section layout of an optical assembly according to one or more implementations.

FIG. 2A is a cross-section diagram of an optical assembly according to one or more implementations.

FIG. 2B is a plan view of the optical assembly shown in FIG. 2A according to one or more implementations.

FIG. 3A is an external three-dimensional (3D) view of an optical assembly according to one or more implementations.

FIG. 3B is an internal 3D view of the optical assembly shown in FIG. 3A according to one or more implementations.

FIG. 4A is a 3D view of a thermal finite element analysis (FEA) simulation for an optical assembly that does not include a thermal dissipation component.

FIG. 4B is a plan view of the FEA simulation for the optical assembly shown in FIG. 4A.

FIG. 4C is a 3D view of an FEA simulation for an optical assembly that includes a thermal dissipation component according to one or more implementations.

FIG. 4D is a plan view of the FEA simulation for the optical assembly shown in FIG. 4C according to one or more implementations.

FIG. 5 is a flowchart of an example process associated with thermal management of optical components.

### DETAILED DESCRIPTION

The following detailed description of example implementations refers to the accompanying drawings. The same reference numbers in different drawings may identify the same or similar elements.

Optical chips (including high-power lasers and Mach-Zehnder (MZ) transmitter chips, among other examples) may integrate one or more photonic elements (such as lasers, modulators, waveguides, amplifiers, and detectors) onto a semiconductor substrate. Additionally, optical chips may be used for long-haul fiber-optic transmission, optical sensing, industrial applications, and/or modulation of optical signals for coherent optical communication, among other examples.

In some examples, an optical chip may operate at an optical power level that may result in substantial heat generation. For instance, some sources of thermal output may include Joule heating from electrical driving circuits, optical absorption in semiconductor materials, and/or nonlinear optical effects within the chip. Additionally, continuous wave (CW) lasers, tunable lasers, and semiconductor optical amplifiers (SOAs) generate heat, as electrical energy is converted into optical output. Similarly, MZ transmitters may be associated with high-speed and/or high-voltage electrical signals to modulate optical signals, resulting in resistive heating in the modulator electrodes and optical loss-related heating in the waveguides. Such heat generation of an optical chip can cause wavelength drift, phase instability, damage to the chip or nearby components, and performance degradation, impacting system reliability and efficiency.

Active cooling and/or materials with a high thermal conductivity may be used to manage the thermal output of optical chips. For instance, optical chips may be bonded to “carriers” made of thermally conductive materials (such as alumina (Al₂O₃), aluminum nitride (AlN), or diamond, among other examples) that efficiently transfer heat. However, such thermally conductive materials provide a limited thermal heat dissipation dictated by the material properties. Additionally, active cooling techniques (such as a fan or a pump) are associated with additional components that increase costs, increase size, and increase power usage of an optical module that includes the optical chip. Being able to improve the thermal management above the limited capabilities of active cooling techniques and/or thermally conductive materials would have benefits that result in increased performance capability of optical chips.

Some implementations described herein provide a thermal dissipation component (e.g., a heat spreading component), such as a chamber (e.g., an evaporation/condensation chamber, a vapor chamber, and/or another thermally conductive chamber), one or more heat pipes, and/or another thermal dissipation component. The thermal dissipation component may serve as an optical chip substrate carrier that is directly attached to an optical chip to manage thermal performance of the chip. Accordingly, the thermal dissipation component reduces an overall temperature of the attached optical chip and thereby reduces a likelihood of performance degradation and/or damage to the optical chip or nearby components related to increased temperatures at the optical chip. Such reductions in temperature of the optical chip may enable a higher output power capability of the optical chip, which may increase performance. Additionally, the thermal dissipation component may dissipate heat at a faster rate as compared to commonly used thermally conductive packaging materials such as Al₂O₃, AlN, and/or diamond. Such increases in the rate of heat dissipation may reduce thermal gradients across the thermal dissipation component, which may reduce localized overheating.

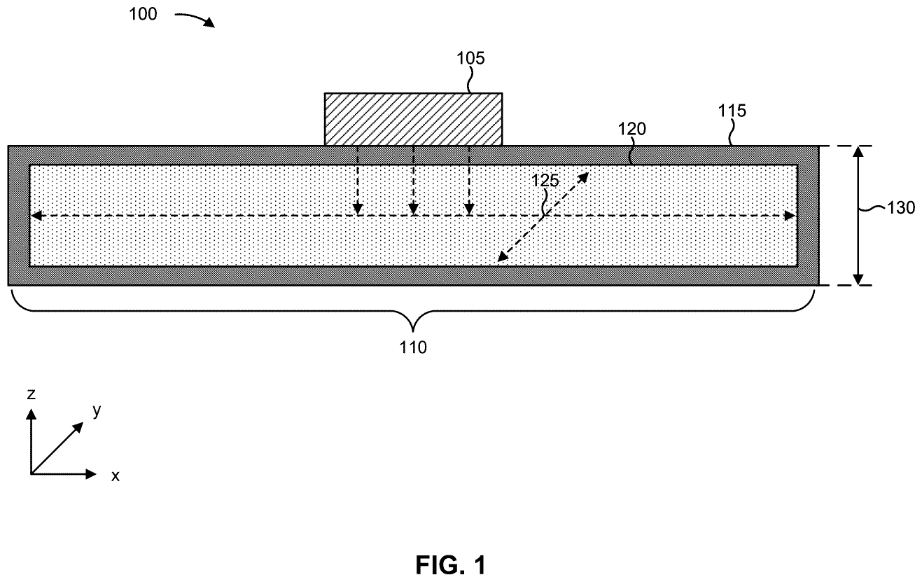

FIG. 1 shows a cross-section layout of an optical assembly 100 according to one or more implementations. The optical assembly 100 may include a thermal dissipation component 110 directly attached to a heat-generating device 105. As shown in FIG. 1, the thermal dissipation component 110 may be directly attached and/or bonded to the bottom or base of the heat-generating device 105.

The heat-generating device 105 may be configured to generate heat during operations. In other words, the heat-generating device 105 may be a device that outputs heat based on performing one or more configured operations. In some implementations, the heat-generating device 105 may be an integrated circuit (IC). For example, an IC may include one or more electronic circuits on a piece (or “chip”) of semiconductor material that integrates various electronic components such as transistors, resistors, and/or capacitors into a single unit to perform circuit-based operations. In some implementations, the heat-generating device 105 may be a transimpedance amplifier (TIA). For example, a TIA may be an electronic device that converts current to voltage and may be used in applications such as optical receivers where the TIA may amplify a current generated by a photodiode into a usable voltage signal. In some implementations, the heat-generating device 105 may be a laser driver. For example, a laser driver may be an electronic circuit or device that provides a current and/or voltage to drive a laser diode, enabling stable operation of a laser. In some implementations, the heat-generating device 105 may be a control circuit. For example, the control circuit may be an electronic circuit designed to manage and regulate the operation of other circuits or devices, and may be used to maintain desired performance parameters such as voltage, current, and/or timing. In some implementations, the heat-generating device 105 may be a digital signal processor (DSP). For example, a DSP may be a microprocessor designed for the processing of digital signals, performing tasks such as filtering, modulation, and/or data compression. In some implementations, the heat-generating device 105 may be a laser source. For example, a laser source may be a device that generates a coherent beam of light through the process of optical amplification based on stimulated emission of electromagnetic radiation. In some implementations, the heat-generating device 105 may be a tunable laser. For example, a tunable laser may be a type of laser whose wavelength of operation can be adjusted or tuned over a specific range, making the tunable laser versatile for various applications such as spectroscopy and signal communications. In some implementations, the heat-generating device 105 may be a pump laser. For example, a pump laser may be used to provide energy to “pump” another laser medium (e.g., in fiber amplifiers and/or solid-state lasers) to achieve population inversion and enable lasing. In some implementations, the heat-generating device 105 may be a photodiode. For example, a photodiode may be a semiconductor device that converts light into an electrical current, used in various applications such as light detection and/or optical communication. In some implementations, the heat-generating device 105 may be an optical transmitter. For example, an optical transmitter may be a device that converts electrical signals into optical signals for transmission over an optical fiber (e.g., typically comprising a light source such as a laser diode and associated drive electronics). In some implementations, the heat-generating device 105 may be an optical receiver. For example, an optical receiver may be a device that converts optical signals into electrical signals (e.g., typically using a photodiode and amplification circuitry, for further processing in optical communication systems). In some implementations, the heat-generating device 105 may be an optical chip that integrates one or more photonic elements (such as one or more lasers, waveguides, amplifiers, and/or detectors, among other examples). For example, an optical chip may be a high-power laser chip and/or an MZ transmitter chip.

As shown in FIG. 1, the optical assembly 100 includes a single heat-generating device 105 attached and/or bonded to the thermal dissipation component 110. In some other implementations, however, the optical assembly 100 may include multiple heat-generating devices 105 that are respectively attached and/or bonded to the thermal dissipation component 110.

In some implementations, the thermal dissipation component 110 may be a substrate (e.g., a carrier). For example, the substrate may serve as a foundational platform upon which various components are mounted (such as the heat-generating device 105). The substrate may include electrical traces, which are conductive pathways that facilitate the connection and communication between different devices and/or components integrated into the optical assembly 100. The electrical traces may enable the routing of signals and power to and from the multiple devices/components of the optical assembly 100. In some implementations, the substrate may also host other devices, such as passive electronic components (e.g., resistors or capacitors) or connectors, which play supportive roles in the overall functionality of the optical assembly 100.

In some implementations, there may be a printed circuit board (not shown) positioned between the heat generating device 105 and the thermal dissipation component 110. The printed circuit board may provide a means for positioning and interconnecting various optical and electronic components while still enabling sufficient thermal connection between the heat generating device 105 and the thermal dissipation component 110.

In some implementations, the thermal dissipation component 110 may contain a phase change material 120 configured to undergo phase transitions between a first phase state and a second phase state. For example, the thermal dissipation component 110 may include a chamber 115 (e.g., a sealed enclosure) that may be evacuated and partially filled with the phase change material 120. In some implementations, the phase change material 120 may comprise one or more materials that transition from a liquid state to a vapor/gaseous state (e.g., evaporation). For instance, the phase change material 120 may include one or more of water (e.g., transitions from liquid to vapor at approximately 100 degrees Celsius (° C.)), ethanol (e.g., transitions from liquid to vapor at approximately 78° C.), or methanol (e.g., transitions from liquid to vapor at approximately 65° C.), among other examples. In some implementations, the phase change material 120 may comprise one or more materials that transition from a solid state to a liquid state (e.g., melting). For instance, the phase change material 120 may include one or more of paraffin wax (e.g., hydrocarbons that melt at various temperatures, typically between 37° C. to 64° C.) or sodium acetate trihydrate (e.g., melts at approximately 58° C.), among other examples. In some examples, the phase change material 120 may comprise one or more materials that transition from a solid state to a vapor/gaseous state (e.g., sublimation). For instance, the phase change material 120 may include naphthalene (e.g., which sublimates at approximately 80° C.), among other examples. The one or more materials included in the phase change material 120 may be based on an operating temperature range of the heat-generating device 105 such that the phase change of the phase change material 120 occurs at a threshold temperature to mitigate thermal issues at the heat-generating device 105 and/or other neighbouring components included in the optical assembly 100.

The chamber 115 of the thermal dissipation component 110 may be made from a thermally conductive material that enables the flow of heat from the heat-generating device 105 to the thermal dissipation component 110. In some implementations, the chamber 115 may comprise one or more metals, metal alloys, and/or ceramic materials. For instance, the chamber 115 may be made of copper, aluminum, nickel, stainless steel, copper-tungsten (CuW) alloy, aluminum-silicon carbide (AlSiC) composite, a nickel-cobalt-iron alloy, AlN, beryllium oxide (BeO), and/or silicon carbide (SiC), among other materials. The one or more materials selected for the chamber 115 may be based on the specific thermal and/or mechanical characteristics of the thermal dissipation component 110, including factors such as thermal conductivity, weight, structural integrity, and/or compatibility with the phase change material 120. Additionally, as shown in FIG. 1, the thermal dissipation component 110 may have a thickness 130. In some implementations, the thickness 130 may be greater than 0.02 millimeters (mm) and less than or equal to 5 mm.

As described herein, the top face of the thermal dissipation component 110 (e.g., a first surface) may be directly attached to the bottom face (e.g., a second surface) of the heat-generating device 105. The heat-generating device 105 may be attached and/or bonded to the thermal dissipation component 110 via soldering (e.g., eutectic gold tin (AuSn) solder or other solder types), flip-chip bonding, epoxy adhesive bonding, thermocompression, and/or anodic bonding, among other examples. Based on the first surface of the thermal dissipation component 110 making contact with the heat-generating device 105, the thermal dissipation component 110 may obtain heat from the heat-generating device 105 in a first direction (e.g., the z-direction, as shown in FIG. 1). As the thermal dissipation component 110 absorbs more heat, particles of the phase change material 120 may start to transition from the first phase to the second phase, where the second phase has more energy than the first phase. Accordingly, the particles that are excited to the second phase may distribute evenly across the space enclosed by the chamber 115, which may distribute the heat evenly across the phase change material 120 and the chamber 115. For example, the phase change material may transition from the first state to the second state (such as evaporating from a liquid to a vapor) when the phase change material 120 comes into contact with an interface of the chamber 115 that satisfies a temperature threshold. Having absorbed heat from the hot interface, the phase change material 120 in the second state may travel within the chamber 115 to a cooler region of the chamber 115, where the phase change material 120 transitions from the second state back to the first state and releases latent heat into a cooler region of the thermal dissipation component 110. Thus, the phase change material 120 may be used to efficiently transfer heat from one area of the thermal dissipation component 110 (e.g., a high-power dissipation area or a hot spot) to another area of the thermal dissipation component 110 (e.g., a low-power dissipation area or a cool spot) to minimize a temperature gradient of the thermal dissipation component 110.

Additionally, as shown in FIG. 1, the phase change material 120 may enable a heat flow 125, where the heat flow may spread in one or more normal directions relative to a first direction in which the heat is received from the heat-generating device 105. For example, the heat flow 125 may spread in a second direction that is perpendicular to the first direction (e.g., spread in the x-direction, as shown in FIG. 1) and may flow in a third direction that is perpendicular to the first direction and the second direction (e.g., spread in the y-direction, as shown in FIG. 1). In other words, the one or more normal directions may comprise a two-dimensional plane that is orthogonal to the first direction (e.g., the x-y plane is orthogonal to the z-direction).

In some examples, the chamber 115 may have a coefficient of thermal expansion (CTE) that is similar to respective CTEs associated with other thermally conductive materials described elsewhere herein (such as Al₂O₃ or AlN). Accordingly, the chamber 115 may thermally expand in ways similar to other thermally conductive materials described herein, such that the thermal dissipation component 110 may replace a traditional substrate without disrupting the configuration of optical assemblies. Additionally, based on incorporating the phase change material 120, the thermal dissipation component 110 may have an associated thermal conductivity that is greater than that of other thermally conductive materials described herein. For example, Table 1 describes the thermal conductivity (e.g., in watt per meter-kelvin (W/mK)) associated with the thermal dissipation component 110 and other thermally conductive materials described elsewhere herein (e.g., Al₂O₃, AlN, and diamond).

TABLE 1

| | Thermal |
|---|---|
| | Conductivity |
| Material | W/mK |
| Al₂O₃ | ~30 |
| AlN | ~230 |
| Diamond | ~2000 |
| Thermal dissipation | ~20000 |
| component 110 | |

A shown in Table 1, the thermal dissipation component 110 may have an associated thermal conductivity that is one or more orders of magnitude greater than that of the other thermally conductive materials. Therefore, the thermal dissipation component 110 may more efficiently distribute heat from the heat-generating device 105, compared to conventional or traditional substrates.

As indicated above, FIG. 1 is provided as an example. Other examples may differ from what is shown in and described with regard to FIG. 1.

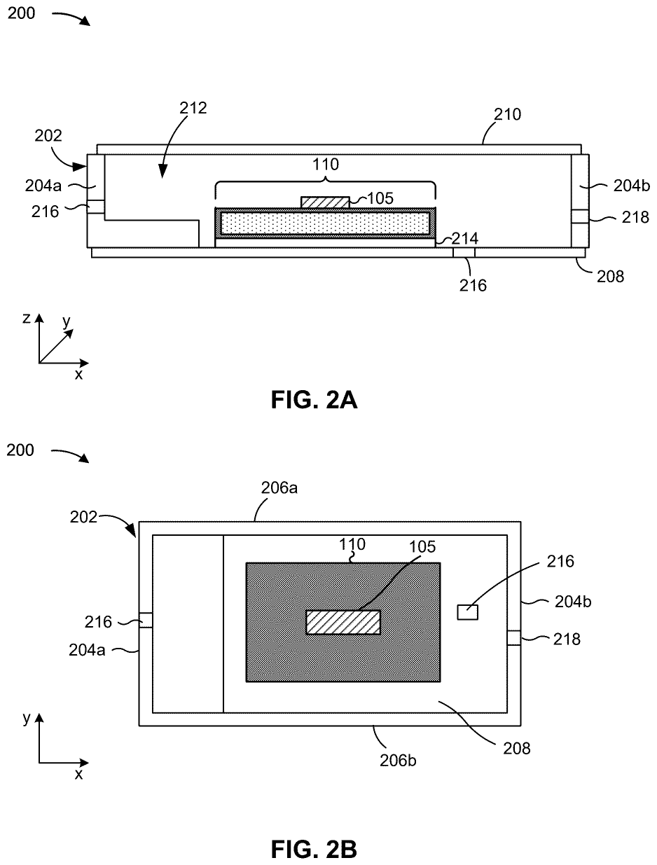

FIG. 2A is a diagram illustrating a cross-section of an optical assembly 200 according to one or more implementations. FIG. 2B is a plan view of the optical assembly 200 shown in FIG. 2A according to one or more implementations. The optical assembly 200 may be an example of or implement one or more aspects of the optical assembly 100 described with reference to FIG. 1. For example, the optical assembly may include the thermal dissipation component 110 and a heat-generating device 105. In some other implementations, the optical assembly 200 may include multiple heat-generating devices 105 attached and/or bonded to the thermal dissipation component 110 or to one or more portions of a housing 202.

The optical assembly 200 includes the housing 202 that may include sidewalls 204a, 204b, 206a, and 206b, a base 208 (e.g., bottom package base) that extends between the sidewalls 204a and 204b in a first planar direction (e.g., an x-direction) and extends between the sidewalls 206a and 206b in a second planar direction (e.g., a y-direction), and a lid 210 (e.g., a top package cover) that is arranged opposite to the base 208 and that extends between the sidewalls 204a and 204b in the first planar direction (e.g., the x-direction) and extends between the sidewalls 206a and 206b in the second planar direction (e.g., the y-direction). The housing 202 may be made of polymer, ceramic, metal, and/or a metal alloy. For example, the housing 202 may be made of a polymer, a ceramic material, a nickel-cobalt-iron alloy, CuW, or any combination of a polymer, ceramic, the nickel-cobalt-iron alloy, and/or CuW. In some implementations, other metals and metal alloys can be used for the housing 202, such as copper molybdenum (CuMo) and/or copper. In some implementations, the housing 202 may be made of multi-metal layers of ceramic in combination with multi-metal layers, or of a polymer in combination with multi-metal layers. The housing 202, together with the sidewalls 204a, 204b, 206a, and 206b, the base 208, and the lid 210, may define an enclosure 212 in which one or more components of the optical assembly 200 are arranged. In addition, the heat-generating device and the thermal dissipation component may be contained in the enclosure 212.

As shown in FIGS. 2A and 2B, the base 208 and the thermal dissipation component may be coupled to a thermoelectric cooler (TEC) 214 (e.g., a bottom face of the TEC 214 makes contact with the base 208, and a top face of the TEC 214 makes contact with the thermal dissipation component). For example, the TEC 214 (also known as a Peltier cooler) may be a solid-state device that uses the Peltier effect to create a heat flux between the junctions of two different types of materials. When an electric current is applied to the TEC 214, heat is absorbed at one junction and dissipated at the other, effectively creating a temperature differential that can be used for cooling. TECs may be compact, reliable, and capable of precise temperature control, making TECs ideal for applications such as cooling components of the optical assembly 200. For example, the TEC 214 may create a temperature differential that moves heat from the thermal dissipation component to the base 208, enabling cooling of the thermal dissipation component. In some other implementations, the optical assembly 200 may not include the TEC 214 in between the base 208 and the thermal dissipation component such that the bottom face of the thermal dissipation component is bonded and/or attached to the top face of the base 208. For example, the base 208 may be soldered or brazed to a ceramic, a metal, and/or a metal alloy of the thermal dissipation component. In other implementations (not shown), the thermal dissipation component 110 may form the base 208 or a portion of the base 208.

In some implementations, the optical assembly 200 may include an electrical feedthrough 216 that is arranged at the base 208 or at a sidewall 204a, 204b, 206a, or 206b. The electrical feedthrough 216 may be configured to receive an electrical receive signal from an outside of the housing 202 and provide the electrical receive signal to one or more components within the enclosure 212 and/or transmit an electrical transmit signal from one or more components within the enclosure 212 to the outside of the housing 202. For example, the electrical feedthrough 216 may be used to receive power signals used for supplying power to one or more components within the enclosure 212 (e.g., the heat-generating devices 105). In some implementations, the electrical feedthrough 216 may be a high-speed feedthrough for transmitting or receiving high-speed data.

In some implementations, the optical assembly 200 may include one or more optical ports 218 (e.g., optical feedthroughs) which may be arranged in the base 208, one or more of the sidewalls 204a, 204b, 206a, 206b, and/or the lid 210. The one or more optical ports 218 may be configured to allow optical signals to pass through the housing 202. For example, the optical signals may include a receive optical signal from an external source (e.g., from an optical transmitter) and/or a transmit optical signal. Thus, the optical assembly 200 may include circuitry and optical components associated with receiving and/or transmitting optical signals. In some implementations, the optical signals may be optical communication signals and the one or more optical ports 218 may be coupled to an optical fiber used for transmitting the optical communication signals.

In some implementations, the housing 202 may be a hermetically sealed housing. Thus, the enclosure 212 may be a hermetically sealed enclosure. Hermetically sealing may protect the components of the optical assembly 200 from oxygen, moisture, and other materials that may otherwise reduce a performance, a reliability, and/or a lifetime of the components of the optical assembly 200.

As indicated above, FIGS. 2A and 2B are provided as examples. Other examples may differ from what is described with regard to FIGS. 2A and 2B. The number and arrangement of devices shown in FIGS. 2A and 2B are provided as an example. In practice, there may be additional devices, fewer devices, different devices, or differently arranged devices than those shown in FIGS. 2A and 2B. Furthermore, two or more devices shown in FIGS. 2A and 2B may be implemented within a single device, or a single device shown in FIG. 2 may be implemented as multiple, distributed devices. Additionally, or alternatively, a set of devices (e.g., one or more devices) shown in FIGS. 2A and 2B may perform one or more functions described as being performed by another set of devices shown in FIGS. 2A and 2B.

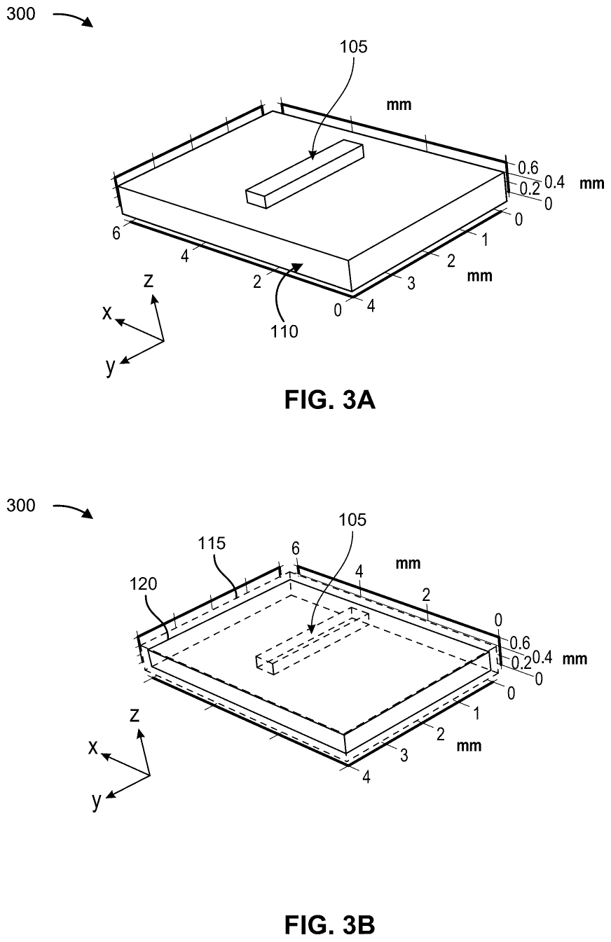

FIG. 3A is an external 3D view of an optical assembly 300 according to one or more implementations. FIG. 3B is an internal 3D view of the optical assembly 300 shown in FIG. 3A according to one or more implementations. The optical assembly 300 may be an example of or implement one or more aspects of the optical assembly described with reference to FIGS. 1, 2A, and 2B. For example, as shown in FIG. 3A, the optical assembly 300 may include the thermal dissipation component 110 and a heat-generating device 105. Additionally, as shown in FIG. 3B, the thermal dissipation component 110 includes the chamber 115 that encloses the phase change material 120.

In the example of the optical assembly 300, the thermal dissipation component 110 may have a length (in the y-direction) of 6 mm, a width (in the x-direction) of 4 mm, and a height (in the z-direction) of 0.4 mm. In some other implementations, the thermal dissipation component 110 may have a different length, width, and/or height. Additionally, in other implementations, the thermal dissipation component 110 may be a shape that is different than a rectangular prism. For instance, the thermal dissipation component 110 may have one or more rounded edges and/or rounded vertices. Additionally, or alternatively, the thermal dissipation component 110 may have a non-rectangular footprint or bottom face (e.g., in the x-y plane).

In the example of the optical assembly 300, the heat-generating device 105 may have a length (in the y-direction) of 3 mm, a width (in the x-direction) of 0.5 mm, and a height (in the z-direction) of 0.2 mm. In some other implementations, the heat-generating device 105 may have a different length, width, and/or height. Additionally, in other implementations, the thermal dissipation component 110 may be a shape that is different than a rectangular prism. In some implementations, the length of the thermal dissipation component 110 may be at least equal to the length of the heat-generating device 105 and may be up to three times the length of the heat-generating device 105.

As described elsewhere herein, if heat is applied to a localized area of the chamber 115 (e.g., the area where the thermal dissipation component 110 contacts the heat-generating device 105), then the phase change material 120 within the chamber 115 may absorb the heat. In some examples, the phase change material 120 may evaporate and turn from liquid into vapor based on absorbing the heat. Accordingly, the vapor may distribute across the space enclosed by the chamber 115 based on a pressure differential caused by the localized area of heat at the chamber 115. Such distribution of the vapor may carry the heat from the localized area across the chamber 115. In some examples, the vapor may condense back into liquid based on distributing to cooler regions of the chamber 115, releasing heat evenly across the chamber 115 and the sealed enclosure of the thermal dissipation component.

As indicated above, FIGS. 3A and 3B are provided as examples. Other examples may differ from what is described with regard to FIGS. 3A and 3B. The number and arrangement of devices shown in FIGS. 3A and 3B 3 are provided as an example. In practice, there may be additional devices, fewer devices, different devices, or differently arranged devices than those shown in FIGS. 3A and 3B. Furthermore, two or more devices shown in FIGS. 3A and 3B may be implemented within a single device, or a single device shown in FIG. 3 may be implemented as multiple, distributed devices. Additionally, or alternatively, a set of devices (e.g., one or more devices) shown in FIGS. 3A and 3B may perform one or more functions described as being performed by another set of devices shown in FIGS. 3A and 3B.

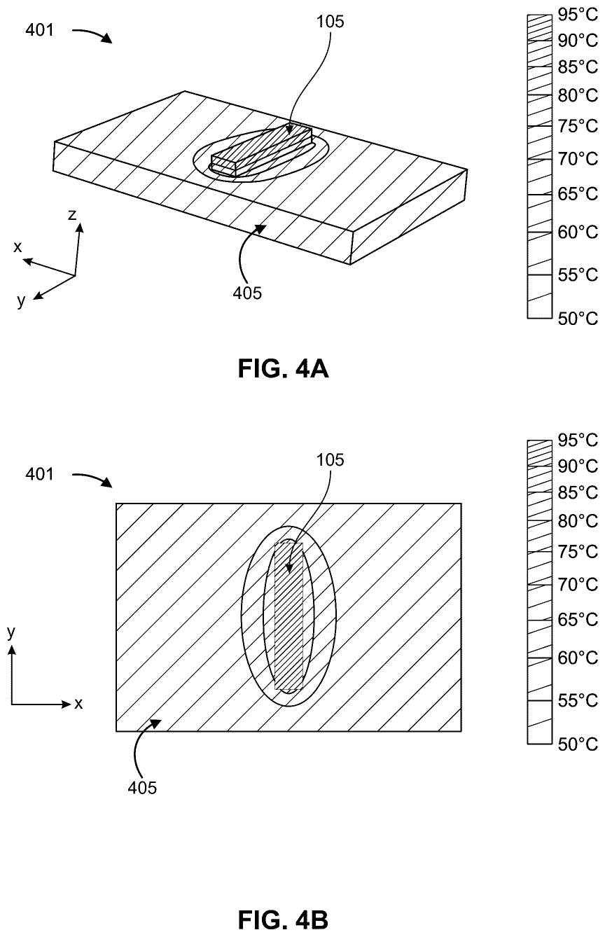

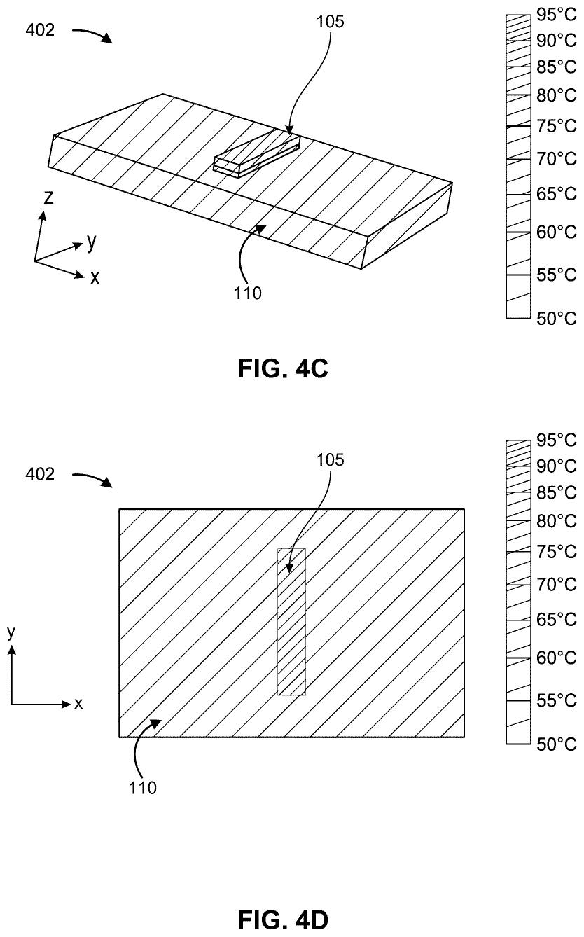

FIG. 4A is a 3D view of a thermal finite element analysis (FEA) simulation for an optical assembly 401 that does not include a thermal dissipation component according to one or more implementations. FIG. 4B is a plan view of the FEA simulation for an optical assembly 401 shown in FIG. 4A. For example, the optical assembly 401 does not include the thermal dissipation component 110 described in connection with FIGS. 1, FIGS. 2A-2B, and/or FIGS. 3A-3B. Rather, the optical assembly 401 includes the heat-generating device 105 that is bonded and/or attached to a substrate 405. The substrate 405 may be an example of a conventional or traditional substrate described elsewhere herein.

As shown in FIGS. 4A and 4B, the top face of the heat-generating device 105 is at a temperature of approximately 95° C. and the bottom face of the heat-generating device 105 that is in contact with the substrate 405 is at a temperature of approximately 75° C. Additionally, the portion of the substrate 405 that is in contact with the heat-generating device 105 is at a temperature of approximately 75° C. and the outer edges of the substrate 405 are at a temperature of approximately 50° C. Therefore, the heat output by the heat-generating device causes a non-uniform distribution of heat across the substrate 405 that results in a temperature differential across the substrate of approximately 25° C.

As indicated above, FIGS. 4A and 4B are provided as examples. Other examples may differ from what is described with regard to FIGS. 4A and 4B.

FIG. 4C is a 3D view of an FEA simulation for an optical assembly 402 that includes a thermal dissipation component according to one or more implementations. FIG. 4D is a plan view of the FEA simulation for the optical assembly 402 shown in FIG. 4C according to one or more implementations. For example, the optical assembly 402 includes the heat-generating device 105 that is bonded and/or attached to thermal dissipation component 110, described in connection with FIGS. 1 through 3B.

As shown in FIGS. 4C and 4D, the top face of the heat-generating device 105 is at a temperature of approximately 80° C. and the bottom face of the heat-generating device 105 that is in contact with the substrate 405 is at a temperature of approximately 70° C. Therefore, the heat-generating device 105 in the optical assembly 402 has a peak operating temperature that is approximately 15° C. lower than the heat-generating device 105 in the optical assembly 402. Additionally, the portion of the thermal dissipation component 110 that is in contact with the heat-generating device 105 is at a temperature of approximately 55° C. and the outer edges of the substrate 405 are at a temperature of approximately 50° C. Therefore, the distribution of heat across the thermal dissipation component 110 is approximately 20° C. less than the distribution of heat across the substrate 405.

As indicated above, FIGS. 4C and 4D are provided as examples. Other examples may differ from what is described with regard to FIGS. 4C and 4D.

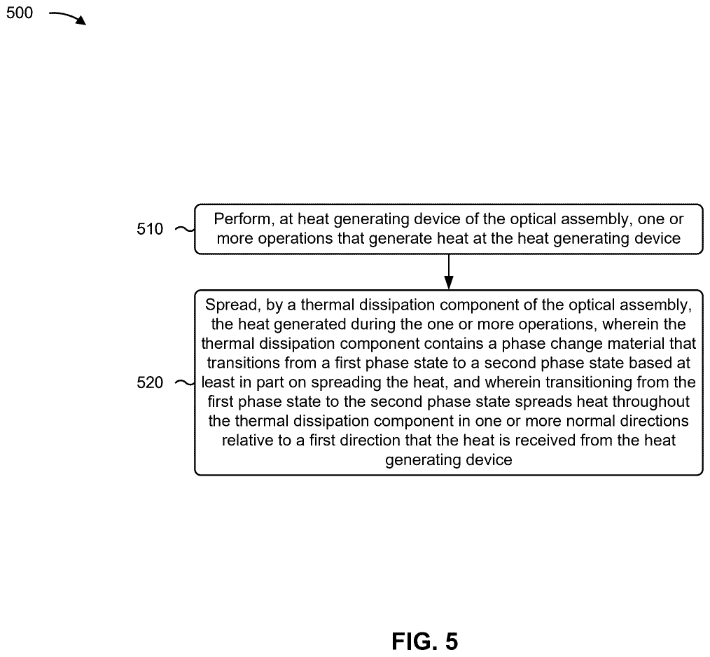

FIG. 5 is a flowchart of an example process 500 associated with thermal management of optical components. One or more process blocks of FIG. 5 are performed by an optical assembly (e.g., optical assembly 100, 200, 300, and 402) and/or by another device or a group of devices separate from or including the optical assembly.

As shown in FIG. 5, process 500 includes performing, at a heat-generating device (e.g., the heat-generating device 105) of the optical assembly, one or more operations that generate heat at the heat-generating device (block 510). For example, the optical assembly may perform, at a heat-generating device of the optical assembly, one or more operations that generate heat at the heat-generating device, as described above.

As further shown in FIG. 5, process 500 includes spreading the heat generated during the one or more operations, wherein the thermal dissipation component (e.g., the thermal dissipation component 110) contains a phase change material that transitions from a first phase state to a second phase state based at least in part on spreading the heat, and wherein transitioning from the first phase state to the second phase state spreads heat throughout the thermal dissipation component in one or more normal directions relative to a first direction in which the heat is received from the heat-generating device (block 520). For example, the optical assembly may spread the heat generated during the one or more operations, wherein the thermal dissipation component contains a phase change material that transitions from a first phase state to a second phase state based at least in part on spreading the heat, and wherein transitioning from the first phase state to the second phase state spreads heat throughout the thermal dissipation component in one or more normal directions relative to a first direction in which the heat is received from the heat-generating device, as described above.

Process 500 may include additional aspects, such as any single aspect or any combination of aspects described below and/or in connection with one or more other processes described elsewhere herein.

In a first aspect, spreading the heat in the one or more normal directions comprises spreading the heat in a two-dimensional plane that is orthogonal to the first direction.

In a second aspect, alone or in combination with the first aspect, the thermal dissipation component is a substrate bonded to the heat-generating device.

In a third aspect, alone or in combination with one or more of the first and second aspects, the thermal dissipation component comprises a chamber that contains the phase change material, and the chamber is made from at least one of a metal, a metal alloy, or a ceramic material.

In a fourth aspect, alone or in combination with one or more of the first through third aspects, the heat-generating device and the thermal dissipation component are contained inside a housing (e.g., the housing 202) that defines an enclosure (e.g., the enclosure 212), wherein the housing comprises sidewalls (e.g., the sidewalls 204) and a base (e.g., the base 208) that extends between the sidewalls.

In a fifth aspect, alone or in combination with one or more of the first through fourth aspects, the thermal dissipation component is bonded to the base.

In a sixth aspect, alone or in combination with one or more of the first through fifth aspects, the base and the thermal dissipation component are coupled to a TEC (e.g., the TEC 214).

In a seventh aspect, alone or in combination with one or more of the first through sixth aspects, the enclosure is hermetically sealed.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, the term “component” is intended to be broadly construed as hardware, firmware, and/or a combination of hardware and software.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical assembly, comprising:
a heat-generating device configured to generate heat during operation; and
a thermal dissipation component, comprising a first surface thermally coupled to a second surface of the heat-generating device to receive the heat generated by the heat-generating device, wherein the thermal dissipation component contains a phase change material configured to undergo phase transitions between a first phase state and a second phase state, and wherein the phase transitions cause the heat to spread throughout the thermal dissipation component in one or more normal directions relative to a first direction in which the heat is received from the heat-generating device.

2. The optical assembly of claim 1, wherein the one or more normal directions comprise a two-dimensional plane that is orthogonal to the first direction.

3. The optical assembly of claim 1, wherein the thermal dissipation component is a substrate bonded to the heat-generating device.

4. The optical assembly of claim 1, wherein the thermal dissipation component comprises a chamber that contains the phase change material, and wherein the chamber is made from at least one of a metal, a metal alloy, or a ceramic material.

5. The optical assembly of claim 1, further comprising:
a housing that defines an enclosure that contains the heat-generating device and the thermal dissipation component, wherein the housing comprises sidewalls and a base that extends between the sidewalls.

6. The optical assembly of claim 5, wherein the thermal dissipation component is bonded to the base.

7. The optical assembly of claim 5, wherein the base and the thermal dissipation component are coupled to a thermoelectric cooler (TEC).

8. The optical assembly of claim 5, wherein the enclosure is hermetically sealed.

9. The optical assembly of claim 1, wherein the heat-generating device is one or more of an integrated circuit, a transimpedance amplifier, a laser driver, a control circuit, a digital signal processor, a laser source, a tunable laser, a pump laser, a photodiode, an optical transmitter, or an optical receiver.

10. The optical assembly of claim 1, wherein the heat-generating device has a first length and the thermal dissipation component has a second length that is less than or equal to three times the first length.

11. The optical assembly of claim 1, wherein the thermal dissipation component has a thickness that is greater than 0.02 millimeters and less than or equal to 5 millimeters.

12. A method at an optical assembly comprising:
performing, at heat-generating device of the optical assembly, one or more operations that generate heat at the heat-generating device; and
spreading, by a thermal dissipation component of the optical assembly, the heat generated during the one or more operations, wherein the thermal dissipation component contains a phase change material that transitions from a first phase state to a second phase state based at least in part on spreading the heat, and wherein transitioning from the first phase state to the second phase state spreads heat throughout the thermal dissipation component in one or more normal directions relative to a first direction in which the heat is received from the heat-generating device.

13. The method of claim 12, wherein spreading the heat in the one or more normal directions comprises:
spreading the heat in a two-dimensional plane that is orthogonal to the first direction.

14. The method of claim 12, wherein the thermal dissipation component is a substrate bonded to the heat-generating device.

15. The method of claim 12, wherein the thermal dissipation component comprises a chamber that contains the phase change material, and wherein the chamber is made from at least one of a metal, a metal alloy, or a ceramic material.

16. The method of claim 12, wherein the heat-generating device and the thermal dissipation component are contained inside a housing that defines an enclosure, wherein the housing comprises sidewalls and a base that extends between the sidewalls.

17. The method of claim 16, wherein the thermal dissipation component is bonded to the base.

18. The method of claim 16, wherein the base and the thermal dissipation component are coupled to a thermoelectric cooler (TEC).

19. The method of claim 16, wherein the enclosure is hermetically sealed.

20. An optical assembly, comprising:
a housing that defines an enclosure, wherein the housing comprises sidewalls and a base that extends between the sidewalls, and wherein one of the sidewalls comprises an optical port configured to at least one of receive a receive optical signal or transmit a transmit optical signal;
at least one component integrated within the enclosure, wherein the at least one component is configured to generate heat during operation; and
a thermal dissipation component inside of the enclosure, wherein:
a first surface of the thermal dissipation component is thermally coupled to a second surface of the at least one component to receive heat from the at least one component,
the thermal dissipation component contains a phase change material that is configured to undergo phase transitions between a first phase state and a second phase state,
the thermal dissipation component is configured to utilize the phase transitions to spread heat throughout the thermal dissipation component in a two-dimensional plane that is perpendicular to a first direction in which the heat is received from the at least one component, and
the thermal dissipation component is configured to equalize at least one of a heat load or a temperature gradient of the at least one component.
